(19) United States
(12) Patent Application Publication
(10) Pub. No.: US 2026/0128100 A1
(43) Pub. Date: May 7, 2026

(54) SYSTEMS AND METHODS FOR VARYING MAXIMUM PROGRAM VOLTAGE

(71) Applicant: Micron Technology, Inc., Boise, ID (US)

(72) Inventor: Jeffrey S. McNeil, Nampa, ID (US)

(73) Assignee: Micron Technology, Inc., Boise, ID (US)

(21) Appl. No.: 19/379,737

(22) Filed: Nov. 4, 2025

Related U.S. Application Data
(60) Provisional application No. 63/716,877, filed on Nov. 6, 2024.

(51) Int. Cl. G11C 16/10; G11C 11/56; G11C 16/04

(52) U.S. Cl. CPC G11C 16/10; G11C 16/0483; G11C 11/5628; G11C 11/5671

(57) ABSTRACT

A memory device is provided. The memory device includes an array of memory cells. The memory cells are multiple-level memory cells. The memory device further includes a controller configured to perform: initiating a programming operation to program selected memory cells of the array of memory cells; and determining a remaining program fail count prior to a last step of the programming operation. The last step of the programming operation corresponds to programming a last level of the selected memory cells of the array of memory cells. The controller is further configured to perform determining a last level program voltage step based on the remaining program fail count value; and causing the last level of the selected memory cells to be programmed based on the last level program voltage step.

### RELATED APPLICATIONS

This application claims priority to U.S. Provisional Application No. 63/716,877, filed on Nov. 6, 2024, entitled “SYSTEMS AND METHODS FOR VARYING MAXIMUM PROGRAM VOLTAGE.” The contents of U.S. Provisional Application No. 63/716,877 are incorporated by reference herein in their entirety for all purposes.

### TECHNICAL FIELD

This disclosure relates to one or more systems for memory, including techniques for varying maximum program voltage during programming operations of a memory device.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 3 is a block diagram of an example apparatus for implementing one or more systems and for performing one or more methods described herein, in accordance with examples as disclosed herein.

FIG. 4 illustrates an example cell threshold voltage distribution diagram for an TLC memory device and example programming pulses.

FIG. 5 illustrates an example cell threshold voltage distribution diagram for a TLC memory device with variable last level program step and example programming pulses in accordance with examples as disclosed herein.

FIG. 6 is an example look-up table for determining the last level program step, in accordance with examples as disclosure herein.

FIG. 7 illustrates a flowchart showing a method or methods that support techniques for varying the last level program step for programming a multi-level memory device in accordance with examples as disclosed herein.

### DETAILED DESCRIPTION

A memory device may include many memory cells. For an single level cell (SLC), each memory cell is configured to store one bit of information. Nowadays, a memory device may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells.

Multiple-level memory cells have multiple threshold voltage levels for storing multiple bits of data. For example, an MLC cell has four threshold voltage levels for storing two bits of data. The two bits per cell belong to two different pages called the lower page (LP) and upper page (UP). A TLC cell has eight threshold voltage levels for storing three bits of data. The three bits per cell belong to three different pages called the lower page (LP), the upper page (UP), and the extra page (XP). Data are stored into multiple-level memory cells by programming them into different pages. An incremental step pulse programming (ISPP) technique is often used for programming multiple-level memory cells. For example, for programming MLC or TLC memory cells, multiple programming pulses are applied to the word line connected to the memory cells. Each of the multiple programming pulses is increased by a voltage step (ΔVpulse) from its immediate previous programming pulse. After each programming pulse, the states of the memory cells are read (called a program verify). If a cell has reached the desired voltage level corresponding to a desired logic state, no further programming pulse is applied. Otherwise, a next programming pulse is applied with the voltage increased by the voltage step (ΔVpulse). For MLC cells, there are four threshold voltage levels corresponding to four logic states, and for TLC cells, there are eight threshold voltage levels corresponding to eight logic states.

During programming operations, program disturb may occur. Program disturb may affect the memory cells that should not be programmed. For example, when programming a particular memory cell B, the program disturb may affect the memory cells on the same word line that do not have to be programmed (e.g., memory cells A and C), because they are biased at the same high word line voltage (e.g., 20V). Memory cells connected to unselected word lines may also be disturbed, but may be to a lesser extent. The program disturb effect becomes worse nowadays because the memory cells are packed more and more densely, different materials and chemical processes are used, and/or other factors making them susceptible to program disturb. Program disturb reduces the read margin. If the amount of the program disturb is sufficient to move a bit beyond the read reference voltage for a certain logic level, it may cause a read failure or error. Therefore, there is a need to reduce the program disturb during programming operations of multiple-level memory cells.

The present disclosure provides technologies for reducing program disturb by reducing the overall maximum program voltage particularly for the last level programming. As described in greater details below, typically, for performing the last level programming, the voltage of the second-last programming pulse is increased by a fixed amount (e.g., 500 mV) to ensure the last level program voltage is greater than the last level cell threshold voltage. As a result, all remaining bits, which failed to be programmed by using previous programming pulses, can be programmed into the memory cells. The voltage increase from the second-last program voltage is also referred to as the last level program voltage step. It may be sometimes bigger than required and thus may cause unwanted program disturb effect.

Technologies described herein reduce the last level program voltage step based on the remaining program fail count. The remaining program fail count represents the percentage of bits that have not been programmed, or failed to be programmed, using the previous programming pulses in the programming operation. The reduced last level program voltage step can in turn reduce the maximum program voltage for the last programming pulse, thereby reducing the program disturb effect. As a result, the read margin and cycling endurance can be improved. In addition, edge memory cells variability can be reduced too. The edge variability refers to the variation of the threshold voltages in edge cells compared to the center cells. And the cycling endurance means the variation of the threshold voltage distribution over the number of memory cycles. For cycling endurance, in general, a smaller variation is better. In addition, the capability to program can become easier. As a result, the overall stress can be reduced by using the method described herein to reduce the final program voltage step, thus improving the cycling endurance of the cells.

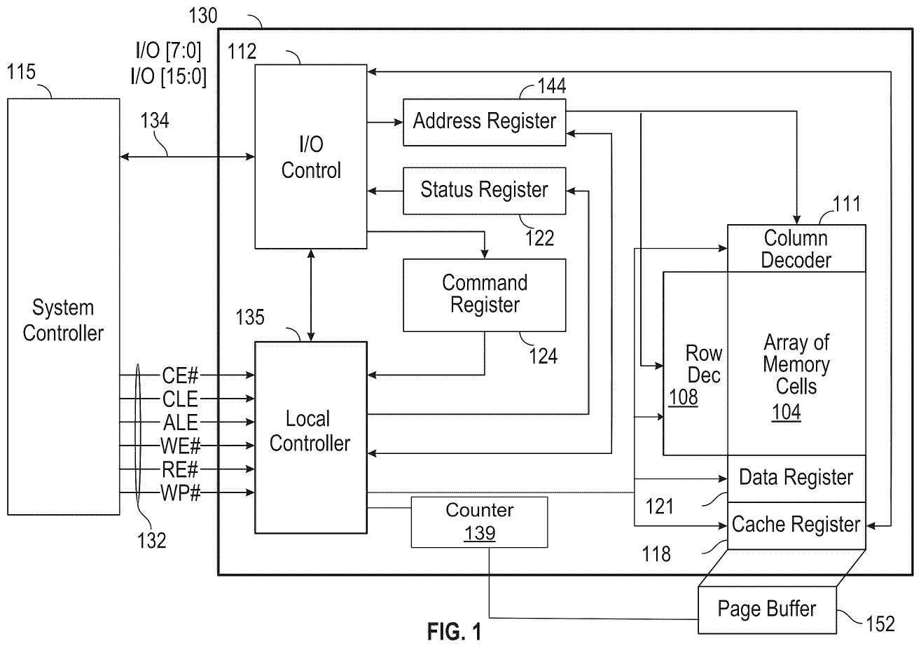

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104. In some examples, during programming operations, page buffer 152 stores data representing the number of bits programmed and/or the number of bits need to be programmed (equivalent to the number of bits failed to program into the memory cells based on previously-applied programming pulses). Such data representing the number of bits need to be programmed is also referred to as the remaining program fail count. In some examples, memory device 130 further includes a counter 139 that can access page buffer 152 to obtain the remaining program fail count stored in a page buffer 152 (e.g., in a latch). Counter 139 may also keep track of the remaining program fail count itself. Counter 139 may be a part of local controller 135, a part of page buffer 152, a part of any circuits in device 130, or a standalone circuit in device 130. Counter 139 can provide the remaining program fail count to local controller 135 for determining the last level program voltage step, such that the last level program voltage can be in turn determined. The methods of determining the remaining program fail count and the last level program voltage step using the controller, counter, and page buffer are described in greater detail below.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

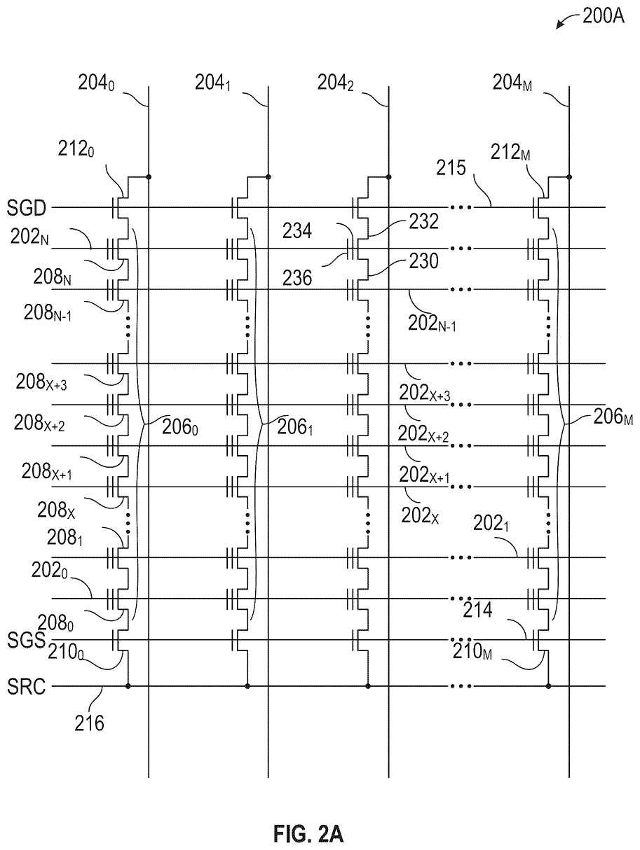

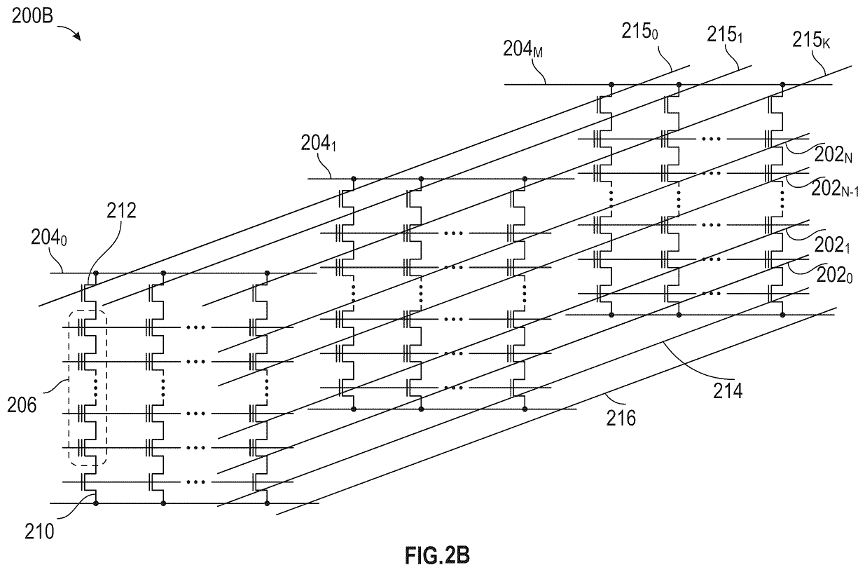

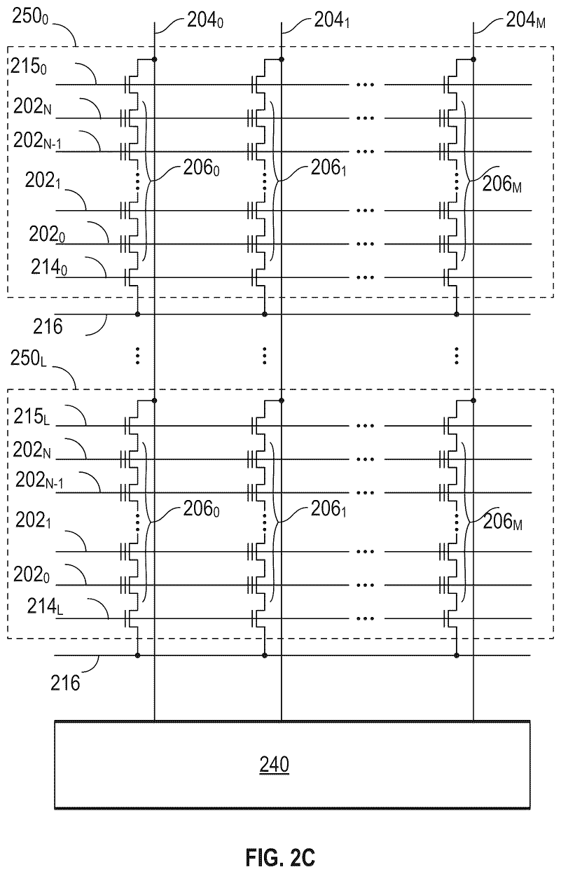

FIG. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{N} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

With reference to FIG. 2C, in some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 250 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

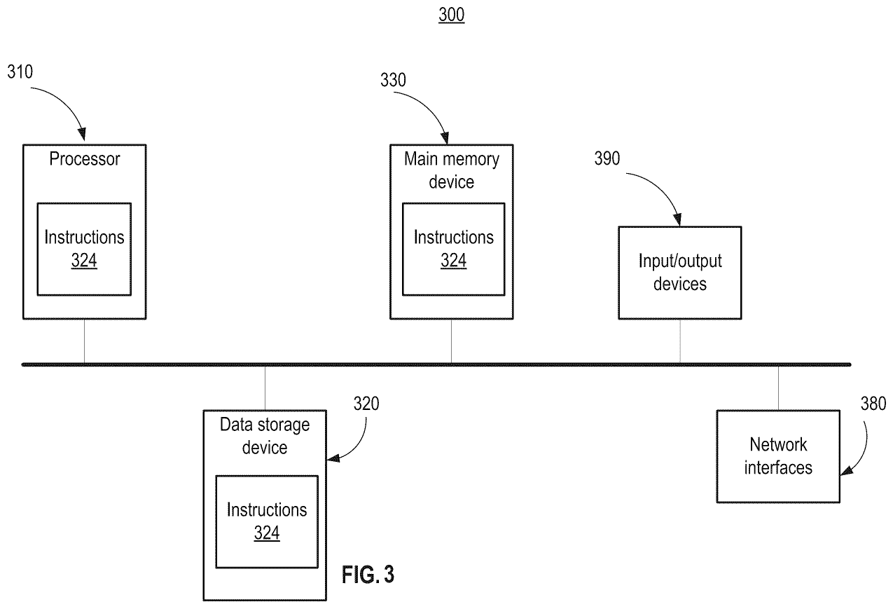

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-7, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-7 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-7. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

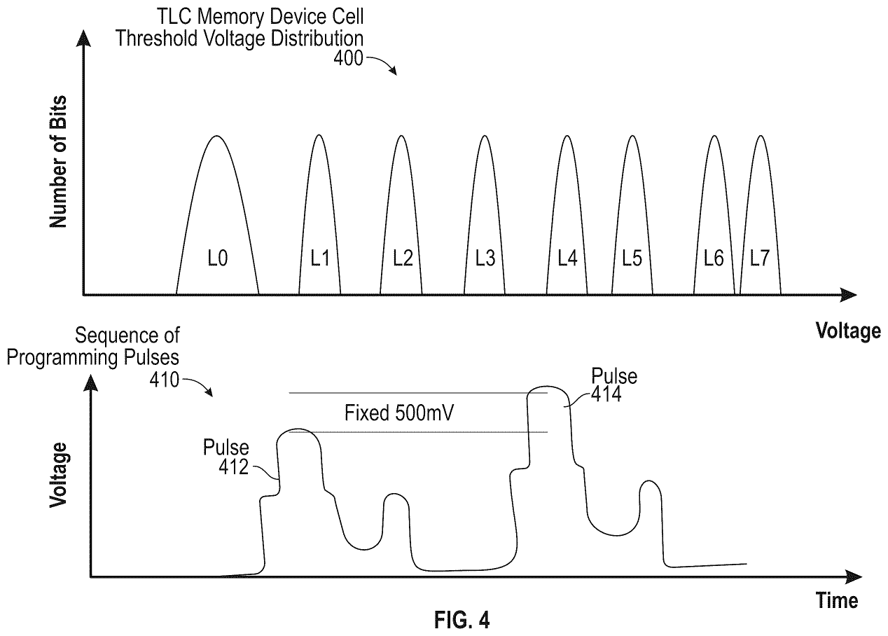

FIG. 4 illustrates an example cell distribution diagram 400 for an TLC memory device and an example sequence of programming pulses 410. As described above, a memory device (e.g., device 130) may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells.

Multiple-level memory cells have multiple threshold voltage levels for storing multiple bits of data. Using the TLC as an example, a TLC has eight threshold voltage levels for storing three bits of data (e.g., 000, 001, 010, 011, 100, 101, 110, and 111) per cell. The three bits per cell belong to three different pages called the lower page (LP), the upper page (UP), and the extra page (XP). Data are stored into multiple-level memory cells by programming them into the different pages. An incremental step pulse programming (ISPP) technique is often used for programming multiple-level memory cells. For example, to program a TLC, a sequence of programming pulses are applied to a word line connected to many memory cells. Two such programming pulses 412 and 414 are shown in FIG. 4. Each of the multiple programming pulses in the sequence is increased by a program voltage step (ΔVpulse) from its immediate-previous programming pulse. After each programming pulse, the states of the memory cells are read (during a program verify phase). If a cell has reached the desired voltage level corresponding to a desired logic state, no further programming pulse is applied to the cell. Otherwise, a next programming pulse is applied with its voltage increased by the program voltage step. For TLC cells, there are eight threshold voltage levels corresponding to eight logic states. The eight logic states are represented by L0-L7 in the cell distribution diagram 400 of FIG. 4.

Ideally, all bits in the multiple-level memory cells are programmed to have precisely the desired threshold voltage. Practically, even being programmed at the same threshold voltage, some bits in some cells are programmed slightly higher than the desired threshold voltage and some bits are programmed slightly lower than the desired threshold voltage, resulting in the curves of L0-L7 shown in cell distribution diagram 400 of FIG. 4. With reference to the cell distribution diagram 400 of FIG. 4, the horizontal axis represents the voltage level and the vertical axis represents the number of bits at each threshold voltage level corresponding to the logic states of L0-L7.

During programming operations, program disturb may occur. Program disturb may affect the memory cells that should not be programmed. With reference back to FIG. 2A, for example, if the memory cell at the intersection of word line 202₀ and bit line 204₁ is to be programmed, the program disturb may affect the memory cells on the same word line 202₀ that do not have to be programmed (e.g., memory cells at the intersection of word line 202₀ and 204₀, and at the intersection of word line 202₀ and 204₂), because they are biased at the same high word line voltage (e.g., 20V). Memory cells connected to unselected word lines (e.g., word lines 2021) may also be disturbed. The program disturb effect becomes worse nowadays because the memory cells are packed more densely, different materials and chemical processes are used, and/or other factors making them susceptible to program disturb. Program disturb can reduce the read margin. With reference back to FIG. 4, the read margin refers to the gap between two adjacent curves in diagram 400. If two adjacent curves (e.g., L6 and L7) overlap with each other, read error or failure may occur because two logic states may not be distinguished. Thus, if the amount of the program disturb is sufficient to move a bit beyond the read reference voltage for a certain logic state, it may cause a read failure or error.

Typically, during a programming operation, the voltage level of the last programming pulse is given a dedicated threshold voltage such that the last programming pulse can be applied without having to perform a following program verify operation. As described above, for programming TLC memory cells, multiple programming pulses are applied to the word line connected to the memory cells. Each of the multiple programming pulses is increased by a program voltage step (ΔVpulse) from the immediate-previous programming pulse. After each programming pulse, the states of the memory cells are read during a program verify operation. If the cell has reached the desired voltage level corresponding to a desired logic state, no further programming pulse is applied. Otherwise, a next programming pulse is applied with its voltage increased by the program voltage step. Typically, the last level program step has a fixed large value (e.g., 500 mV) such that the last level program voltage (i.e., the maximum program voltage among all programming pulses) is large enough to ensure all remaining bits are programmed into the memory cells. Thus, after this last programming step, there is no need to have a program verify operation.

FIG. 4 illustrates two programming pulses 412 and 414 in the sequence of programming pulses 410. Pulse 414 is the last level program pulse and pulse 412 is the second-last level program pulse. Therefore, pulse 414 has the maximum program voltage that is used to program bits that have not been programmed by using the previous programming pulses like pulse 412. After applying pulse 414, the memory cells should have the corresponding logic state (e.g., L7). To reach the maximum program voltage, the voltage level of programming pulse 414 is increased from that of pulse 412 by a fixed amount (e.g., 500 mV). This fixed amount of the last level program voltage step is usually selected to be large enough to ensure that the programming operation can be completed with all remaining bits programmed without having to perform another program verify operation. This large fixed amount of the last level program voltage step for the last programming pulse 414 may cause severe program disturb. As described above, program disturb reduces the read margin. If the amount of the disturb is sufficient to move a bit beyond the read reference voltage for a certain logic level, it may cause a read failure or error. The present disclosure provides technologies for reducing the program disturb during programming operations of multiple-level memory cells.

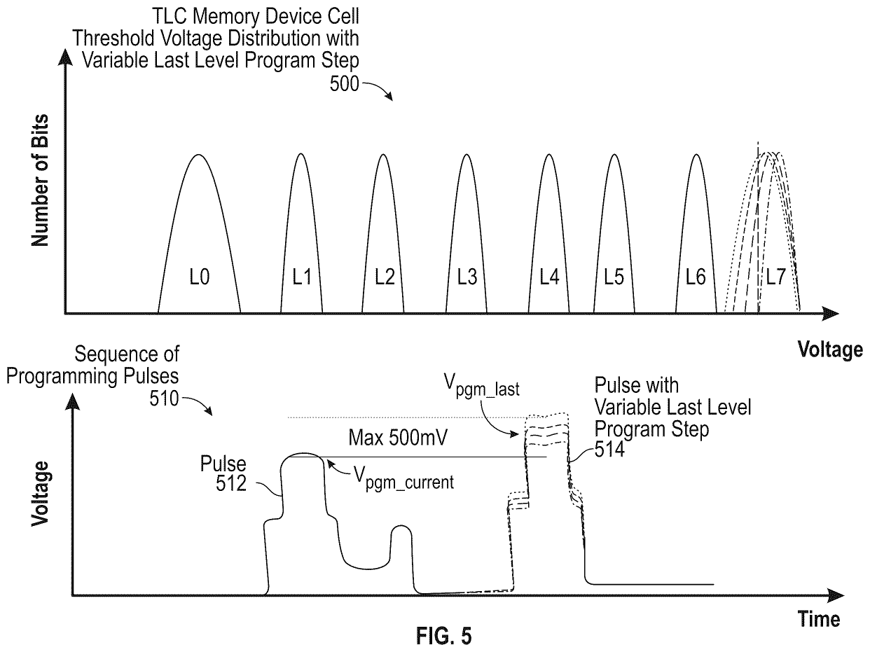

FIG. 5 illustrates an example cell threshold voltage distribution diagram 500 for a TLC memory device with variable last level program voltage step and an example sequence of programming pulses 510 in accordance with examples as disclosed herein. In FIG. 5, the sequence of programming pulses 510 also shows the second-last programming pulse 512 and the last programming pulse 514. Instead of increasing the voltage level by a fixed large amount (e.g., 500 mV) from the second-last programming pulse 512 to the last programming pulse 514, the last level program voltage step from pulse 512 to pulse 514 can be reduced to a smaller value (e.g., 100 mV, 200 mV, 300 mV, 400 mV, etc.), thereby reducing the program disturb. The specific process of achieving such a reduced last level program voltage step is described in detail next.

With reference to FIGS. 1, 2A, and 5, a controller (e.g., controller 135 or 115) can initiate a programming operation to program selected memory cells by using, for example, a sequence of programming pulses 510. The sequence of programming pulses 510 shown in FIG. 5 only includes the last two programming pulses, but it can include more programming pulses prior to the last two programming pulses 512 and 514. The previous programming pulses can be used to program the memory cells to have lower threshold voltages (e.g., corresponding to lower logic states L1-L5) compared to pulses 512 and 514. Because those programming pulses are not specifically related to the process described herein, they are omitted from diagram 510 of FIG. 5.

The controller can apply the sequence of programming pulses 510 to a word line to program selected memory cells connected to the word line. The word line may be, for example, word line 202₀ shown in FIG. 2A. The same word line may be connected to other memory cells that are not being programmed (e.g., they have already being programmed using previous programming pulses). During the programming operation, the controller can apply multiple programming pulses to the word line connected to the selected memory cells. Each of the multiple programming pulses is increased by a program voltage step (ΔVpulse). After each programming pulse, the states of the selected memory cells are read during a program verify operation. If a cell has reached the desired threshold voltage level corresponding to a desired logic state, the controller applies no further programming pulses. Otherwise, a next programming pulse is applied with the voltage increased by the program voltage step.

In some example, during a programming operation, the controller can be configured to determine that the next programming pulse is the last programming pulse for programming the last level of the selected memory cells. The last programming pulse is the last pulse in the sequence of programming pulses. The controller can make such a determination based on a current level program voltage and/or a remaining program fail count threshold. For example, the controller may determine that for the current programming pulse (e.g., the second-last programming pulse 512), the programming voltage is already at a particular level. Based on this current level program voltage, the controller can predict or estimate that increasing the current level program voltage further may make the program voltage reach the last level program voltage. In other words, there is no further increasing of the program voltage after the next level. If the controller determines that the next level program voltage is the last level program voltage, the controller can determine that the next programming pulse is correspondingly the last programming pulse (e.g., pulse 514).

In some examples, the controller can determine if the next programming pulse is the last programming pulse based on a remaining program fail count threshold. As described above, after each programming pulse, the controller performs a program verification operation to determine if a memory cell has reached the desired threshold voltage level corresponding to a desired logic state. The controller can obtain the number of bits that have not reached the desired threshold voltage level and thus have not been programmed into the memory cells. This number of bits is also referred to as the remaining program fail count. For example, after the first programming pulse is applied, there may be 20% of the cells that have been programmed and 80% of the cells that have not reached their desired logic states. Therefore, the remaining program fail count is 80%. After the fourth or fifth programming pulse, the remaining program fail count may drop to, e.g., 30%. And after the last programming pulse, the remaining program fail count should drop to approximately zero (i.e., all memory cells should have been programmed after the last programming pulse).

The remaining program fail count may be obtained by the controller and/or a counter (e.g. counter 139). The remaining program fail count may be stored in the page buffer 152. The controller may obtain the current remaining program fail count during the programming operation and compare it with a remaining program fail count threshold. For instance, if the remaining program fail count threshold is 25%, and if the current remaining program fail count is no greater than 25%, the controller may determine that the next programming pulse is the last programming pulse. The remaining program fail count threshold can be preconfigured or dynamically changed.

In some examples, during a programming operation, based on the program verification results, the controller can determine a remaining program fail count prior to the last step of the programming operation. The last step of the programming operation corresponds to programming the last level of the selected memory cells. For example, with reference to FIG. 5, the controller may determine that the next programming pulse 514 is the last programming pulse and therefore applying the next programming pulse 514 to the word line is in the last step of the programming operation. In some examples, the controller may also determine a remaining program fail count based on the results of the program verification operation following the programming pulse 512. As described above, the remaining program fail count represents the remaining number of bits to be programed for the last level of the selected memory cells. The remaining program fail count, or a representation thereof, can be stored in the page buffer (e.g., page buffer 152). Thus, the controller can obtain the remaining program fail count from the page buffer (directly or via a counter like counter 139).

Next, based on the remaining program fail count, the controller can determine the last level program voltage step. The last level program voltage step is the incremental amount that is added to the current level program voltage. The sum of the current level program voltage and the last level program voltage step is then used as the voltage level of the last programming pulse. For example, in FIG. 5, if the current level program voltage for the second-last programming pulse 512 is denoted as V_{pgm_current}, and the last level program voltage step is determined to be Δ_{pgm_last}, the voltage level of the last programming pulse 514 is then V_{pgm_last}=V_{pgm_current}+Δ_{pgm_last}.

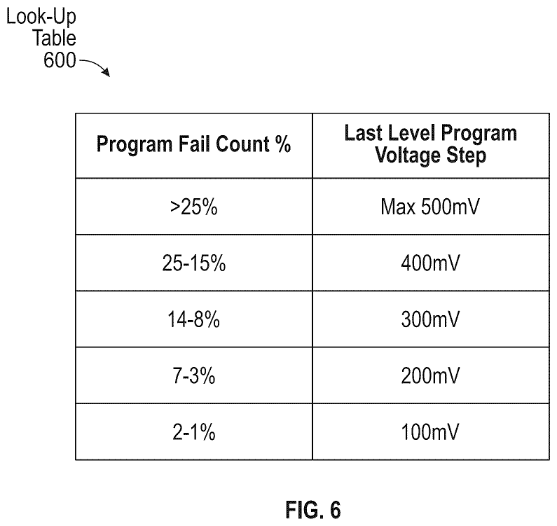

In the examples described herein, the last level program voltage step is a variable. In some embodiments, it can be determined using a fail-count threshold lookup table. An example of such a table is shown in FIG. 6. In FIG. 6, table 600 is a fail-count threshold lookup table representing relations between fail-count threshold values and corresponding program voltage steps. In one example, the fail-count threshold values comprise fail-count percentage thresholds. For example, in FIG. 6, the fail-count percentage thresholds are greater than 25%, between 25% and 15%, between 14% and 8%, between 7% and 3%, or between 2% and 1%. Their corresponding program voltage steps are 500 mV, 400 mV, 300 mV, 200 mV, or 100 mV, respectively. Thus, in this example, based on table 600, if the controller determines that the remaining program fail count (obtained prior to the last programming pulse 514) is greater than 25%, the last level program voltage step is selected to be 500 mV. Thus, the current level program voltage (for pulse 512) should be increased by 500 mV for the last programming pulse (pulse 514). If the controller determines that the remaining program fail count is between 25% and 15%, the last level program voltage step is reduced to 400 mV. Thus, the current level program voltage (for pulse 512) should be increased by only 400 mV for the last programming pulse (pulse 514). Similarly, the last level program voltage step can be further reduced to, for example, 100 mV if the controller determines that the remaining program fail count is between 1-2%. In other words, the less the number of bits remaining to be programmed, the smaller the last level program voltage step can be.

By reducing the last level program voltage step, the last level program voltage for the last programming pulse 514 is also reduced. As described above, reducing the program voltage for a programming pulse can reduce the program disturb effect and therefore improve the read margin. As shown in FIG. 6, when the last level program voltage step is the maximum (e.g., 500 mV), the read margin between the logic states L6 and L7 is minimum (and may not have any). As the last level program voltage step reduces (and therefore the last level programming voltage or the maximum program voltage reduces), the read margin between the logic states L6 and L7 improves because of less program disturb effect.

Comparing the programming pulses 514 and 414 in FIGS. 5 and 4, respectively, based on the remaining program fail count threshold (e.g., those shown in the table 600), the last level program voltage step can be reduced relative to a predetermined last level voltage step (e.g., a fixed amount of 500 mV regardless of the remaining program fail count). In some examples, the last level program voltage step in the lookup table (e.g., table 600) is configured to be no greater than a maximum program voltage step threshold (e.g., 500 mV) during the programming operation.

As described above, FIG. 6 shows an example table 600 representing the relation between fail-count threshold values and corresponding program voltage steps. In some examples, one such lookup table can be established per word line. In other examples, one or more other factors may be included in the lookup table. For example, the lookup table may further takes into account one or more environmental factors and/or one or more manufacturing factors. For instance, for each predetermined temperature (e.g., 20 degrees, 30 degrees, . . . 90 degrees, 100 degrees, etc.), the lookup table may include a relation between the remaining fail-count threshold values and corresponding program voltage steps. The relations for different temperatures may be different. For example, if the memory device is operating under a hot temperature, the last level program voltage step may be larger than that of a cold temperature (e.g., 125 mV v. 75 mV). This means that under the hot temperature, the incremental amount for the last level program voltage step may be further reduced compared to that of the cold temperature. Similarly, the lookup table may establish a relation between the remaining fail-count threshold values and corresponding program voltage steps for each of different device fabrication conditions. It is understood that the lookup table can be constructed in any desired manner and not limited to those described above.

In some examples, the last level program voltage steps included in a lookup table may be predetermined based on testing or measurement results. And therefore, they meet a threshold for omitting a program verify phase for the last step of the programming operation. In other words, even if the last level program voltage level is reduced based on the lookup table, all remaining bits can still be programmed and no program verification operation is required after the last programming pulse is applied.

The above-described process determines the last level program voltage step and thus applies to only the last programming pulse for a program operation of multiple-level memory cells. In other words, during the programming operations, program voltages other than the last level program voltage are fixed. They do not change based on the current remaining program fail count. In other examples, they may change depending on the implementation.

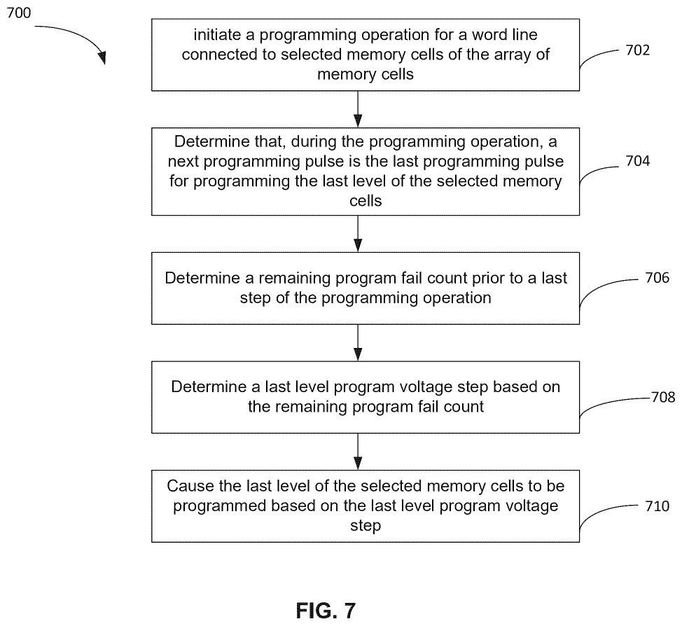

FIG. 7 illustrates flowcharts showing a method 700 that supports techniques for varying the last level program step for programming a multi-level memory device in accordance with examples as disclosed herein. Method 700 can be performed by a controller of a memory device. In block 702, the controller, coupled with the array of memory cells, is configured to initiate a programming operation to program selected memory cells of the array of memory cells.

In block 704, the controller is further configured to perform, prior to determining the remaining program fail count, determining that, during the programming operation, a next programming pulse is the last programming pulse for programming the last level of the selected memory cells. In some examples, as described above, the controller determines that the next programming pulse is the last programming pulse based on at least one of: a current level program voltage; or a remaining program fail count threshold.

In block 706, the controller determines a remaining program fail count prior to a last step of the programming operation. The last step of the programming operation corresponds to programming a last level of the selected memory cells of the array of memory cells. The remaining program fail count represents the remaining number of bits to be programed for the last level of the selected memory cells. In some examples, the controller is further configured to store a representation of the remaining number of bits to be programed in the page buffer of the array of memory cells.

In block 708, the controller determines a last level program voltage step based on the remaining program fail count value. The determining of the last level program voltage step is based on a fail-count threshold lookup table representing relations between fail-count threshold values and corresponding program voltage steps. In some examples, the fail-count threshold values comprise fail-count percentage thresholds associated with the corresponding program voltage steps. The fail-count percentage thresholds include, for example, at least one of the following remaining bit percentage thresholds: greater than 25%, between 25% and 15%, between 14% and 8%, between 7% and 3%, or between 2% and 1%. And the corresponding program voltage steps include, for example, at least one of the following steps: 500 mV, 400 mV, 300 mV, 200 mV, or 100 mV. In some examples, the relations represented by the fail-count threshold lookup table are further between the fail-count threshold values, one or more environmental factors, one or more manufacturing factors and the corresponding program voltage steps.

In some examples, during the programming operation, the controller is further configured to cause a counter to obtain, from a page buffer, the remaining program fail count representing the remaining number of bits to be programed.

In the present disclosure, the last level program voltage step is a variable program voltage step. Moreover, the last level program voltage step meets a threshold for omitting a program-verify phase for the last step of the programming operation.

In some examples, based on the remaining program fail count threshold, the last level program voltage step is reduced relative to a predetermined last level voltage step. For example, the last level program voltage step is configured to be no greater than a maximum program voltage step threshold during the programming operation.

In some examples, during the programming operation, program voltages other than the last level program voltage are fixed.

In block 710, the controller causes the last level of the selected memory cells to be programmed based on the last level program voltage step.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
an array of memory cells, the memory cells being multiple-level memory cells; and
a controller, coupled with the array of memory cells, the controller being configured to perform:
initiating a programming operation to program selected memory cells of the array of memory cells;
determining a remaining program fail count prior to a last step of the programming operation, wherein the last step of the programming operation corresponds to programming a last level of the selected memory cells of the array of memory cells;
determining a last level program voltage step based on the remaining program fail count value; and
causing the last level of the selected memory cells to be programmed based on the last level program voltage step.

2. The memory device of claim 1, wherein the controller is further configured to perform, prior to determining the remaining program fail count:
determining that, during the programming operation, a next programming pulse is the last programming pulse for programming the last level of the selected memory cells.

3. The memory device of claim 2, wherein determining that the next programming pulse is the last programming pulse is based on at least one of:
a current level program voltage; or
a remaining program fail count threshold.

4. The memory device of claim 1, wherein the remaining program fail count represents a remaining number of bits to be programed for the last level of the selected memory cells.

5. The memory device of claim 4, further comprising a page buffer, wherein the controller is further configured to perform:
storing a representation of the remaining number of bits to be programed in the page buffer of the array of memory cells.

6. The memory device of claim 1, wherein the determining the last level program voltage step is based on a fail-count threshold lookup table representing relations between fail-count threshold values and corresponding program voltage steps.

7. The memory device of claim 6, wherein the fail-count threshold values comprise fail-count percentage thresholds associated with the corresponding program voltage steps.

8. The memory device of claim 7, wherein the fail-count percentage thresholds include at least one of the following remaining bit percentage thresholds: greater than 25%, between 25% and 15%, between 14% and 8%, between 7% and 3%, or between 2% and 1%.

9. The memory device of claim 7, wherein the corresponding program voltage steps include at least one of the following steps: 500 mV, 400 mV, 300 mV, 200 mV, or 100 mV.

10. The memory device of claim 6, wherein the relations represented by the fail-count threshold lookup table are further between the fail-count threshold values, one or more environmental factors, one or more manufacturing factors and the corresponding program voltage steps.

11. The memory device of claim 1, wherein during the programming operation, the controller is further configured to cause a counter to obtain, from a page buffer, the remaining program fail count representing the remaining number of bits to be programed.

12. The memory device of claim 1, wherein the last level program voltage step is a variable program voltage step.

13. The memory device of claim 1, wherein the last level program voltage step meets a threshold for omitting a program-verify phase for the last step of the programming operation.

14. The memory device of claim 1, wherein based on the remaining program fail count threshold, the last level program voltage step is reduced relative to a predetermined last level voltage step.

15. The memory device of claim 1, wherein the last level program voltage step is configured to be no greater than a maximum program voltage step threshold during the programming operation.

16. The memory device of claim 1, wherein during the programming operation, program voltages other than the last level program voltage are fixed.

17. A memory system comprising:
a processor; and
a memory device coupled to the processor, the memory device comprising:
an array of memory cells, the memory cells being multiple-level memory cells; and
a controller, coupled with the array of memory cells, the controller being configured to perform:
initiating a programming operation to program selected memory cells of the array of memory cells;
determining a remaining program fail count prior to a last step of the programming operation, wherein the last step of the programming operation corresponds to programming a last level of the selected memory cells of the array of memory cells;
determining a last level program voltage step based on the remaining program fail count value; and
causing the last level of the selected memory cells to be programmed based on the last level program voltage step.

18. A method for programming multi-level memory cells in an array of memory cells in a memory device, the method comprising:
initiating a programming operation for a word line connected to selected memory cells of the array of memory cells;
determining a remaining program fail count prior to a last step of the programming operation, wherein the last step of the programming operation corresponds to programming a last level of the selected memory cells of the array of memory cells;
determining a last level program voltage step based on the remaining program fail count; and
causing the last level of the selected memory cells to be programmed based on the last level program voltage step.
